(19) United States
(12) Patent Application Publication
(10) Pub. No.: US 2016/0336153 A1
(43) Pub. Date: Nov. 17, 2016

(54) POINT-TO-POINT CORONA DISCHARGE IN ADMIXTURES OF INERT GAS, OXYGEN, DRY AIR, AND ACETYLENE

(71) Applicants: Patrick Dennis Pedrow, Moscow, ID (US); Rokibul Islam, Pullman, WA (US); Karl Richard Englund, Moscow, ID (US); Shuzheng Xie, Pullman, WA (US)

(72) Inventors: Patrick Dennis Pedrow, Moscow, ID (US); Rokibul Islam, Pullman, WA (US); Karl Richard Englund, Moscow, ID (US); Shuzheng Xie, Pullman, WA (US)

(73) Assignee: Washington State University, Pullman, WA (US)

(21) Appl. No.: 15/154,185

(22) Filed: May 13, 2016

Related U.S. Application Data
(60) Provisional application No. 62/160,813, filed on May 13, 2015.

(51) Int. Cl. H01J 37/32; C23C 16/455; C23C 16/50

(52) U.S. Cl. CPC H01J 37/32458; C23C 16/50; C23C 16/455; H01J 37/32009; H01J 37/32715; H01J 37/32541

(57) ABSTRACT

The provision of blunt protrusions on a grounded screen of a plasma reactor in combination with a working gas diluted with a predominant quantity of an inert gas provides enhanced back corona discharge and greatly increased quantities of neutral radicals near and below the grounded screen of a plasma reactor vessel operated at near atmospheric pressure. Use of helium as the inert gas allow production of reactive species of oxygen, nitrogen or both.

### CROSS-REFERENCE TO RELATED APPLICATIONS

This application claims benefit of priority of U.S. Provisional Application 62/160,813, filed May 13, 2015, which is hereby incorporated by reference in its entirety.

### FIELD OF THE INVENTION

The present invention generally relates to processing of materials and organic matter using a plasma and, more particularly, to generation of neutral radicals for such processing by increasing coulombic discharge in atmospheric pressure, weakly ionized plasma.

### BACKGROUND OF THE INVENTION

Many processes are known that include generation of a plasma by causing a discharge in gases and mixtures thereof for the treatment of materials and substances by material deposition, removal, implantation or exposure to reactive chemical species generated by or resulting from a corona discharge. Perhaps the most widespread use of plasmas has developed in semiconductor device manufacturing where plasmas are developed at extremely low pressures in a vacuum chamber that can contain relatively large objects such as a semiconductor wafer. Very low pressures are favored for such processes since the charged particles and electrons combine and are neutralized when they collide and a deep vacuum pressure provides a much longer mean free path for the charged particles and electrons developed by the discharge creating the plasma prior to re-combination; allowing the charged particles to be manipulated by magnetic and electrical fields to perform a desired process. However, use of a deep vacuum pressure requires the vacuum to be broken and the deep vacuum re-established when workpieces (e.g. wafers) are changed.

On the other hand, numerous plasma processes are being currently investigated for treatment of very small objects and granular materials having particle sizes as small as one micron or less such as achieving plasma polymerize deposition on so-called wood flour or the like for which more-or-less continuous feed (e.g. using a conveyor mechanism) into and out of the plasma chamber are desirable and other organic materials such as food or even living organisms which cannot withstand a deep vacuum. For example, reactive oxygen/nitrogen species (RONS) which may be developed using a plasma are destructive of viruses and virus-like agents such as prions which transmit “mad-cow disease” and other severe neurological maladies. RONS are also capable of achieving microbial reduction in food processing or preservation as well as promoting rapid healing of wounds. Accordingly, atmospheric pressure weakly ionized plasmas (APWIPs), also commonly referred to as cold plasmas, are currently of substantial interest as avoiding a need for a deep vacuum by providing reactant or precursor gases at very low concentration in an admixture with an inert gas in which the reactive particles are greatly diluted and separated in much the same way that a deep vacuum provides increased separation between charged particles and electrons to extend the time a particle can remain charged even though the mean free path is very short. That is, the particle motion regimes are very different between deep vacuum plasma systems and APWIPs. In deep vacuum plasma systems, the mean free path distance between particle collisions is increased and the motion of charged particles can be controlled with comparative ease using electrical and magnetic fields whereas in APWIPs, particle motion is highly collisional and governed principally by gas flow through the plasma reactor, convection, diffusion, and particle mobility on which magnetic fields have only a vanishingly small effect.

Further, charged particles are virtually non-existent outside the discharge gap and neutral particles which may remain chemically activated (referred to herein as “neutral radicals”) are not affected or controllable at all by electrical or magnetic fields. Moreover, spark discharge to such materials or organisms must be scrupulously prevented and dielectric barriers capable of preventing spark discharge further complicate and reduce activated particle motion in the vicinity of a workpiece. (Dielectric barriers are also undesirable as possibly be a vehicle for contamination of the plasma reactor or gases therein.) Therefore, such a particle motion regime causes substantial difficulties in providing adequate numbers of reactive species and causing them to impinge upon a workpiece. Accordingly, many potential processes using cold plasmas have not been practical or even possible due to the insufficiency of populations of activated chemically reactive species at a workpiece surface.

### SUMMARY OF THE INVENTION

It is therefore an object of the present invention to provide a plasma reactor capable of producing significantly increased populations and concentrations of activated chemically reactive species outside the discharge gap of a plasma reactor and proximate to the surface of a workpiece.

It is another object of the present invention to provide an electrode geometry in a plasma reactor vessel significantly increased populations and concentrations of activated chemically reactive species at locations outside the discharge gap of a plasma reactor vessel and avoid any need for a dielectric barrier to avoid spark discharge.

It is a further object of the invention to provide an apparatus and method for efficiently performing plasma polymerized deposition onto any substrate surface and treatment of organic materials and organisms with reactive oxygen/nitrogen species (RONS), reactive oxygen species (ROS, or reactive nitrogen species (RNS) by appropriate choice of carrier gas and working gas(es).

It is yet another object of the present invention to provide a plasma reactor vessel capable of sustaining a cold plasma and scalable to any size.

In order to accomplish these and other objects of the invention, a plasma reactor vessel capable of producing a plasma at near-atmospheric pressures is provided comprising an enclosure having an inlet and outlet for a gas mixture and establishing a gas flow, the gas mixture being predominantly an inert gas to inhibit quenching of inert radicals in the enclosure, an array of needle shaped high voltage electrodes connected to a high voltage source, a screen at substantially ground potential, an array of protrusions having blunt profiles and extending toward the array of needle shaped high voltage electrodes, the array of protrusions being at substantially the potential of the screen, a workpiece support proximate to a side of the screen opposite to the protrusions, whereby back corona discharge and ion production are enhanced near the screen and ions of a gas in the gas mixture are neutralized at the screen to become neutral radicals which are transported to a location of the workpiece support by the gas flow before being quenched.

In accordance with another aspect of the invention, a method of treatment of a material with a plasma at near atmospheric pressure is provided comprising steps of diluting a precursor or reactant gas with a predominant amount of an inert gas to provide a gas mixture at near atmospheric pressure, and producing a flow of the gas mixture through a plasma reactor vessel, applying a high voltage to an array of elongated needle electrodes to cause a multi-point to multi-point plasma discharge between the needle electrodes and protrusion supported and electrically connected to a grounded screen, whereby back corona discharge is enhanced at a location proximate to the grounded screen and neutral radicals pass through the grounded screen to a workpiece.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 is a schematic illustration of a plasma reactor vessel in accordance with the invention which includes illustration of structures and apparatus by which performance measurements were made,

FIG. 2 is an angled view of a grounded screen with protrusions in accordance with the invention,

FIGS. 3A and 3B are, respectively, photographs of the stable corona discharge produced by the invention and the significant back corona generation near the tips of the protrusions on the grounded screen illustrated in FIG. 2,

FIGS. 4A and 4B are oscillograms of corona current including streamer pulses in an argon/acetylene plasma for positive and negative half-cycles of the energizing current, respectively,

FIGS. 5A and 5B are expanded views of portions of FIGS. 4A and 4B that show, with increased clarity, streamer current pulses and their behavior during positive and negative energizing current, respectively,

FIGS. 6A and 6B provide a comparison of the average discharge power of the invention with a needle-to-plane discharge gap geometry for positive and negative half cycles of energizing current,

FIGS. 7A and 7B are corona mode maps of conductance and power in an argon/acetylene plasma for different discharge gap distances and excitation voltages,

FIGS. 8A and 8B graphically illustrate streamer current pulses for positive and negative half cycles of energizing current in an argon/oxygen plasma,

FIGS. 9A and 9B are corona mode maps of conductance and power in an argon/oxygen plasma for different discharge gap distances and excitation voltages,

FIGS. 10A, 10B and 10C are photographs that compare the appearance of corona discharges using the reactor vessel of FIG. 1 and a gas mixture having helium as the inert gas and working gases of acetylene, dry air and, oxygen, respectively.

FIGS. 11A and 11B are expanded oscillograms that show streamer current pulses and their behavior for positive and negative half-cycles using a helium/oxygen gas mixture,

FIG. 12 is a corona mode map of conductance and power in a helium/oxygen plasma,

FIGS. 13A and 13B are expanded oscillograms that show streamer current pulses and their behavior for positive and negative half-cycles using a helium/dry air gas mixture, and

FIG. 14 is a corona mode map of conductance and power in a helium/dry air plasma.

### DETAILED DESCRIPTION OF A PREFERRED EMBODIMENT OF THE INVENTION

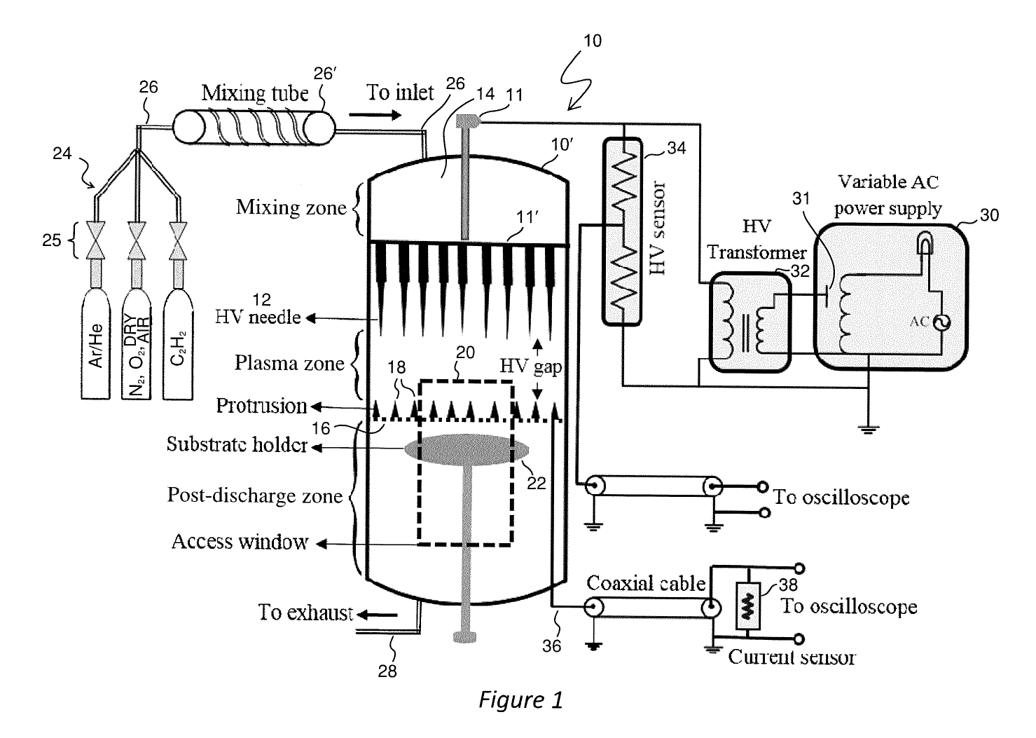

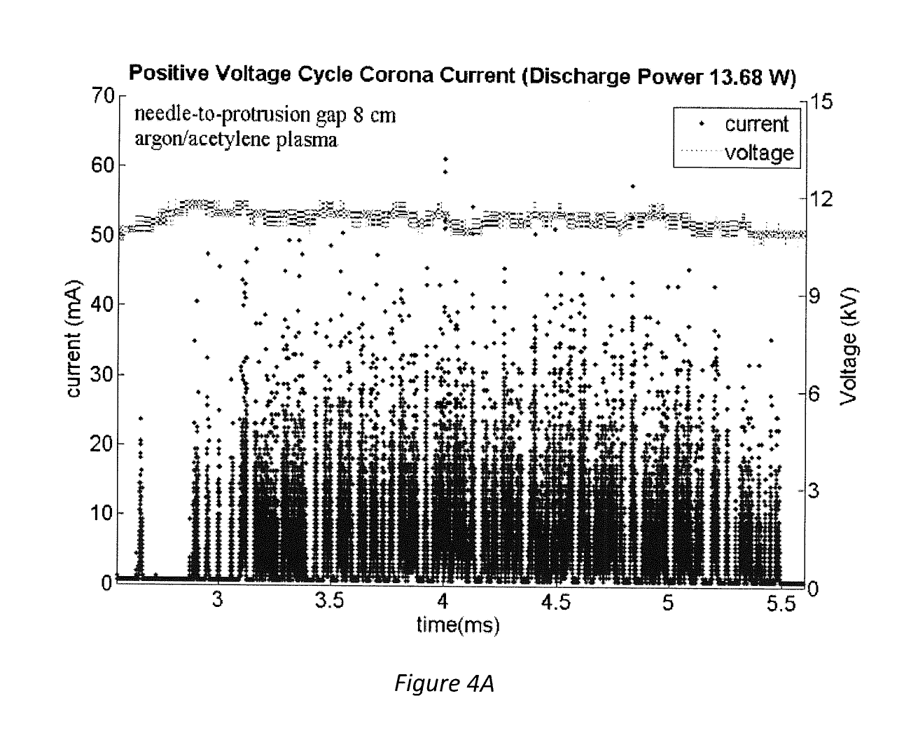

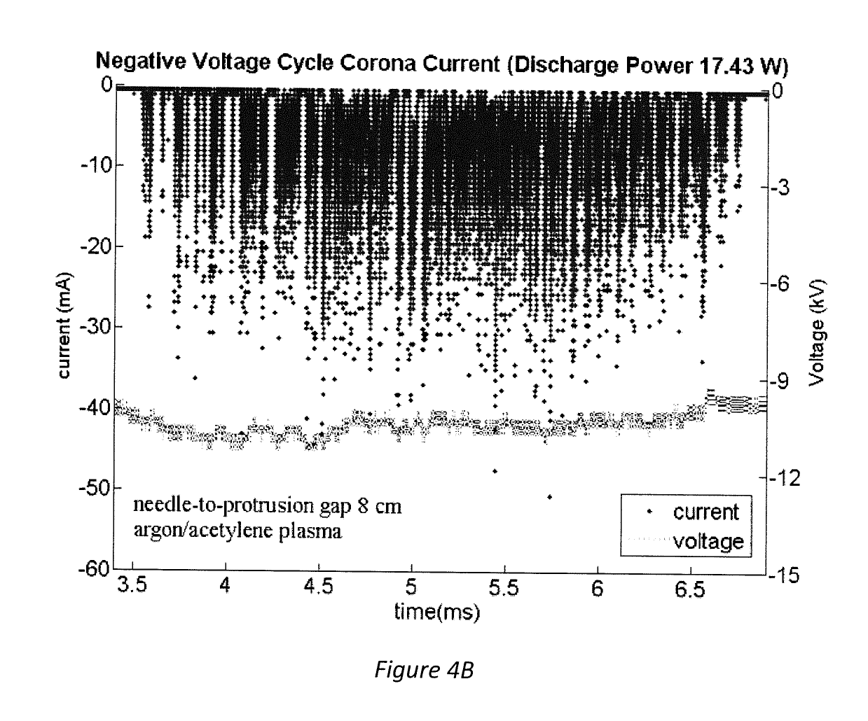

Referring now to the drawings, and more particularly to FIG. 1, there is schematically shown a plasma reaction vessel 10 in accordance with the invention together with the apparatus for operating it and measuring the performance thereof as will be discussed in detail in connection with FIGS. 4A-14. It should be understood that while the invention includes numerous features common to plasma reactor vessels known in the art, it also includes distinctive features in accordance with the invention which provide unexpected and meritorious effects when used in combination and particular configurations with features that may be known. Further, FIG. 1 is arranged to facilitate conveyance of an understanding of the present invention. Therefore, no portion of FIG. 1 is admitted to be prior art in regard to the present invention.

It should also be appreciated that the mechanics, physics, and chemistry (beyond a very few gas mixtures) of plasmas are not fully understood and are the subject of much study and experimentation at the present time. In the course of such study, some terminology has developed to describe particular aspects of a plasma; some of which is somewhat at odds with terms and expressions that are familiar in other scientific fields. Accordingly, unless otherwise explained in the following text, particular terminology and its connotations in regard to the invention will be provided at appropriate points throughout this specification. For example, it should be understood the word “corona”, without qualifying words or terms is generic to all discharge modes exclusive of sparks that may occur therein such as forward corona (the discharge occurring near to or propagating away from a sharply pointed electrode having a small radius of curvature (e.g. an array of long high voltage (HV) needle electrodes 12) which maximizes the electrical field in its vicinity), back corona (the discharge occurring near to or propagating away from a grounded blunt electrode which, in the preferred embodiment of the invention comprises a metal screen with short protrusions that have a radius of curvature that is larger than the radius of curvature of the HV needle electrodes but, prior to the invention, usually a planar screen, the back corona being so-called by reference to the forward or front corona). The word corona is also inclusive of primary and secondary streamers (characterized by frequent and rapidly rising discharge current pulses with peak amplitude five to ten times greater than the most recent mean current). Primary streamers advance into nearly charge-free gas while secondary streamers advance into the residual trail of charged species generated by a primary streamer. Similar terminology can be applied to tertiary, quaternary, and so forth streamers. All streamers are associated with highly non-uniform electrical fields and are stochastic in nature. They are, in appearance, thin, branched filamentary channels propagating through phenomena that include electron avalanches, photoionization, and electron drift in the enhanced local electric field and are pre-phase of the problematic spark discharge which is avoided by the invention. The problem of the streamer-to-spark transition tendency has limited the use of corona discharge in plasma applications.

In contrast to the rapidly rising streamer current pulses is the lower frequency and lower amplitude current signal nominally called the “glow” discharge current associated with non-streamer electron avalanches but also associated with the slow “clean out” or “drift” of ions remaining from previous streamer events. The relationship and dynamics of streamers to other discharge modes such as the glow discharge are not well-understood; however, it is understood that both streamers and glows result in bond scission and the generation of chemically active, neutral, radical chemical species that are essential for plasma-assisted materials processing.

As shown in FIG. 1, plasma reactor vessel 10 comprises a schematically illustrated enclosure 10′ made of Plexiglas™ or other suitable material which is not at all critical to the practice of the invention other than being an insulator and relatively rigid and dimensionally stable since the reaction vessel is intended to operate very near atmospheric pressure (e.g. 0.5 to 2.0 atmospheres) and need only provide accurate electrode spacing (within a reasonably wide tolerance) over a temperature range having an upper bound of substantially less than one hundred degrees centigrade. The volume of the prototype is about seven liters with inside and outside diameters of about fourteen and fifteen centimeters, respectively. An access door with a sealing gasket (not shown) of arbitrary dimensions and design is also provided. The overall design of the reactor vessel follows well-known and established design equations for producing self-sustaining streamer propagation.

The upper portion of the reactor vessel includes a substantial empty volume that functions as a mixing chamber to provide a substantially homogeneous mixture of gases. Electrode 11, preferably of stainless steel, is provided at the top of the reactor vessel and includes a perforated plate, also preferably of stainless steel to separate the mixing zone 14 and the plasma zone below it and support needle electrodes 12 while allowing the gas(es) to flow therethrough parallel to the axes of the needle electrodes 12. The perforations were 0.635 cm in diameter circularly distributed in the prototype. The circular distribution tends to increase uniformity of gas flow across the area of the plasma zone. The needle electrodes are sharply pointed and preferably formed of nickel-coated steel. The needle electrodes protrude downwardly from plate 11′ for a substantially arbitrary distance on the order of several inches (7.62 cm with a radius of curvature of approximately 50 μm in the prototype) and the tips thereof are preferably coplanar but may form a slight contour to adjust plasma density across the area of the plasma zone. The density of needle spacing is not critical but a more closely spaced and dense array tends to favor a larger volume of coulombic discharge reflected as increased discharge current. It is also known that the range of ultraviolet photons in the working gas can be used as a scale length for determining needle-to-needle spacing to enhance needle-to-needle synergism via photoionization which becomes a source of electrons that initiate electron avalanches. Preferably, a number (four in the prototype) of additional very small holes at the periphery of each needle electrode 12 to pass a flow of the gas or gas mixture close to the surface thereof.

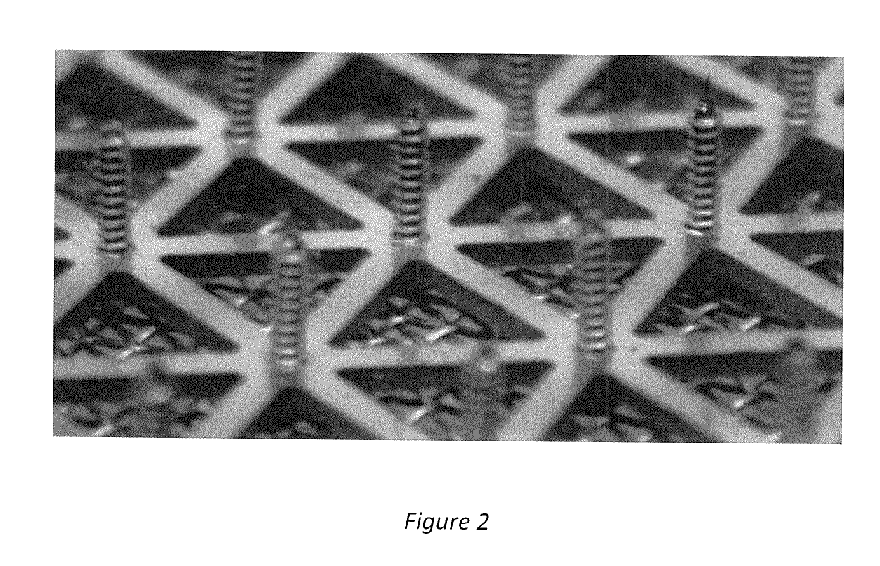

A grounded screen 16 is placed at an adjustable distance below the tips of the needle electrodes 12 and, in accordance with the invention, an array of protrusions 18 are formed thereon. The grounded screen is secured in place with a stainless steel ring (having a diameter of 11.35 cm in the prototype) which is supported against the reactor vessel walls by three springs attached to the ring; allowing the position of the screen to be adjustable through the access door alluded to above to adjust the discharge gap and height of the plasma zone. The grounded screen is formed with apertures that preferably cover the majority of the area of the grounded screen. In the prototype, the grounded screen has an average of seven wires per inch with a wire diameter of 0.45 mm for an average open area of 47%. The grounded screen preferably also includes a substantially rigid stainless steel lattice, preferably with triangular apertures as shown in FIG. 2 to assure the substantial planarity and support the protrusions 18 which are preferably formed in the shape of a slightly tapered helix, also shown in FIG. 2, such that the upper ends of the protrusions are somewhat flat and circular. The overall profile shape of the protrusions is preferably that of a cylinder or truncated cone, possibly with a somewhat convex upper surface and having a height of about 1 cm and a radius of curvature of about 150 μm. In the prototype, fifty-five protrusions are provided with a spacing of about one centimeter between them. The volume below the grounded screen 16 forms a post-discharge zone having a shape approximated by dashed line 20 and which can accommodate some type of substrate or material holder 22 which preferably allows some adjustment of positioning in a direction parallel to the axis of the plasma reactor vessel and gas flow.

None of these design parameters of the prototype are critical since the reaction vessel is scalable to any size with the only limitation being the limit of the excitation voltage that can be economically obtained which, for the prototype was 10.8 kV with a line frequency of 60 Hz obtained through the inexpensive expedient of a commercially available variable transformer known as a Variac™ and a further 1:100 turns ratio partial discharge-free high voltage transformer (so-called because it is designed to be free of partial discharges that otherwise would occur in bubbles in the insulation that attempts to become a spark but are not full discharges since there are no electrodes associated with the bubble and the discharge dissipates quickly and recurs within seconds or a fraction of a second, causing electrical noise that would comprise accuracy of electrical measurements). When scaling the plasma reactor vessel to different sizes, it is, of course, preferable to use the well-established design equations alluded to above but it is believed that the invention can be successfully practiced by maintaining approximate proportionality to the dimensions of the prototype plasma reactor vessel as described above.

FIG. 1 also illustrates the preferred arrangement for developing the desired mixture of gases and the gas flow regime in the reactor vessel described above. Specifically, bottles or tanks 24 of pressurized gases are provided in accordance with the processing to be performed and more or fewer different gases may be provided. For example, as will be discussed below, an inert gas will generally be included which is generally argon but it has been found that helium provides enhanced results for processes that include oxygen and dry air (which also includes nitrogen). However, since argon is less expensive than helium, argon is preferred for processes in which it is adequate. The other bottles or tanks 22 illustrated in FIG. 1 are labeled as containing working gases such as molecular oxygen or nitrogen or dry air, containing both, used in respective types of processes of particular interest and the other is labeled as containing acetylene used in another type of process of particular interest, both of which have been alluded to above and will be described in detail below. However, the gases illustrated should be understood as being exemplary and other gases can be provided as the process of interest may dictate, for example, dry air and molecular nitrogen. Valves 25 allow the volume and relative concentration of each gas to be separately and independently controlled. For example, the inert gas may be used in the absence of the other gases and at increased volume to purge the reaction chamber of contaminants or to displace other gases that may be introduced along with the material to be treated, particularly if the material is in a pulverized or powdered form.

The desired gases are directed into an inlet tube 26 where some mixing will inherently take place due to particle mobility, relative velocity, and shear forces developed by the gas flow adjacent to the inlet tube walls. However, it is preferred to also provide a mixing tube 26′ in the inlet tube 26. Such mixing tubes are commercially available and generally include an enlarged conduit having baffles therein that cause turbulence and/or swirling of the gas flow in the mixing tube. Mechanical agitation may also be provided to ensure a substantially homogeneous mixture of the gases. However, particulars of the optional mixing tube, if provided, are not at all important to the successful practice of the invention.

Inlet tube 26 provides the desired gases to mixing chamber 14, described above where further mixing takes place due to kinetic collisions, convection, and the like before being passed into the plasma zone of the reactor vessel where the plasma is formed. After the ions produced by the plasma have been largely neutralized (hence, the term “weakly ionized”) and neutral radicals passed in the vicinity of the workpiece where processing of the workpieces occurs, the remaining gases are exhausted through exit tube 28.

More specifically, in the plasma zone of the reactor vessel, a small fraction of the injected atoms and molecules are ionized (e.g. weakly ionized). In addition to the ionization in the plasma zone, there are a substantial number of bond scission events (mostly resulting from high speed free electrons colliding with chemical species in the gaseous feed stream) that generate neutral chemical radicals and it is commonly known that charged ions in the gap are substantially outnumbered by these neutral radicals that have resulted from bond scission events. In addition, there are some neutral radicals that emerge when charged chemical species are neutralized. However, the majority of neutral radicals result from bond scission events. The importance of positive ions is that they are the source of the free electrons that sustain the corona discharge and simultaneously engage in bond scission events. It is assumed that the grounded screen intercepts all charged species in the flow stream and thus only neural atoms, neutral molecules, and neutral activated chemical radicals pass through the grounded screen and can be incident upon the substrate zone of the reactor.

Additionally, FIG. 1 includes schematic illustration of the power supply circuit and measurement arrangement for the prototype plasma reaction vessel in accordance with the invention. As alluded to above, the relatively small-scale prototype reaction vessel is preferably powered by a variable AC power supply 30, in the case in the form of an autotransformer where the number of secondary turns is determined by a slidable wiper contact 31 to develop a selectively variable output voltage at the AC line frequency (e.g. 60 Hz). Other relatively low frequencies such as a line frequency of 50 Hz would be equally suitable. However, a DC excitation voltage is not suitable since it is known to lead to long-term instability, specifically sparks, since DC voltage allows for continuous charge accumulation on the insulating walls of the reactor vessel. This variable voltage is connected to the primary winding of a HV transformer with a large turns ratio (e.g. 1:100) to develop a sufficiently high voltage to initiate and sustain a corona discharge including streamers. In this case, the high voltage was thus variable from about 4.11 kV up to 10.08 kV RMS which is applied to electrode 11 as described above. The applied high voltage can be measured using a series connected resistor pair as a voltage divider sensor 34 to proportionally reduce the voltage for measurement using a meter or oscilloscope. Noise is preferably limited by use of a shielded coaxial cable, as shown. The discharge current is measured through a direct connection 36 to the grounded screen 18 described above. The grounded screen is effectively grounded through a small (e.g. 50 ohm termination) resistance 38 which develops a small voltage proportional to the current passing through it while keeping the voltage so developed to a sufficiently low level as to be negligible relative to the discharge voltage even though the grounded screen is not, strictly speaking, actually grounded. The data obtained from operation of the reactor vessel of FIG. 1 both with and without protrusions as discussed above will be presented for comparison as will be discussed in connection with FIGS. 4A-14.

It should also be appreciated that the principal structural difference of the invention from other plasma reactor vessels designed to produce self-sustaining streamer propagation by the inclusion of an array of protrusions 18 on the grounded screen 16 in combination with needle electrodes 12 to provide a multi-point to multi-point discharge electrode geometry rather than a known multi-point to planar grounded screen geometry. The investigation of multi-point to multi-point discharge phenomena in various feed gas streams has not been widely represented in the literature to date. Corona discharges near multi-point ground structures have principally studied to explain the effect of electric field enhancement near the tips of trees, leaves and other sharply pointed objects such as lightning rods at the earth's surface during thunderstorms.

Similarly, back corona has also been observed in plasmas and has been known for its detrimental effect on electrostatic precipitators and studied with a ground plate covered with fly ash, acrylic powder, and other insulating materials where pores or cracks serve to enhance the electrical field without having a grounded surface extending toward the HV electrode(s). Some practical applications of using the back corona in plasma processes include decomposing hydrocarbon contaminants but such possible applications have not been explored extensively.

The basic mechanism of the invention in regard to the use of RONS or reactant precursor species in the types of reaction alluded to above is to generate ions and neutral radicals of the working (e.g. reactant or precursor) gas(es). Ions are predominantly intercepted at the grounded screen 16 but some ions in the gap can be neutralized by recombination and left in a highly chemically activated state referred to as a “neutral or neutralized radical” (e.g. having dangling valence bonds) capable of reacting with the workpiece material. Direct bond scission is also a common source of neutral radicals in the gap; a phenomenon which does not involve ions. For example, plasmas that include oxygen in the feed stream of working gas will contain oxygen ions, O⁺ (sometimes referred to by chemists as charged radicals) which can be neutralized by collision with an electron to generate atomic “neutral radical” oxygen, O, which is extremely chemically active as compared with molecular oxygen, O₂. A closely related example is that oxygen plasma also results in negative ions, O⁻, that would convert to atomic neutral oxygen upon the loss of the extra electron. While molecular oxygen, O₂, is still sufficiently active chemically to oxidize other materials such as aluminum and, in the presence of water, causing iron to rust, it is comparatively very stable while atomic oxygen, the neutral radical O, is far more likely to chemically react with other materials or substances. However, when either O₂ or O collides with an inert gas atom, it remains O₂ or O, respectively. The state of O₂ or O is not changed. In regard to the neutral radical, O, the lack of change is referred to as the neutral radical not being “quenched”; indicating that its highly activated state is maintained. In short, it should be clearly understood, especially in regard to terminology as used herein, that an ion can be neutralized to form a neutral radical without the neutral radical being quenched to a more stable but still potentially chemically reactive state. In addition, many neutral radicals result from bond scission, a process that does not involve ions. Similar chemistry is applicable for nitrogen which has been found to present many of the same challenges in plasma as oxygen; a solution for which will be discussed below. Thus, the presence of a predominant portion of the gas being an inert gas (a ratio of inert gas to working gas of about 40:1 to about 50:1 is preferred) allows substantial duplication of conditions in a low pressure, deep vacuum plasma reactor since the neutral radicals collide relatively seldom with species that can quench them notwithstanding the very short mean free path in an atmospheric pressure plasma reactor and the travel distance to the workpiece or substrate is small compared to the travel distance to a quenching collision.

Note that in the gap or plasma zone of the reactor vessel, the ratio of neutral radicals generated by bond scission to charged ions is relatively large. It follows that the reactor in accordance with the invention utilizes positive ions and a source of free electrons that sustain the corona discharge but also cause bond scission events in substantial numbers to a greater extent than neutralization of ions to yield neutral radicals.

The inventors have found that the use of multiple sharp projections from the ground plane toward the HV electrodes can enhance back corona and influence other discharge modes. Since the back corona is placed close to the grounded screen by the projections, the invention seeks to enhance the back corona as much as possible while maintaining streamers to enhance the population of ions in a self-sustaining plasma discharge to enhance the number and density of neutralized radicals and to transport them to a workpiece location by the flow of gas in the plasma reactor vessel. This is achieved in accordance with the invention by providing a gas admixture which principally comprises inert gas as a carrier and to provide relatively blunt profile protrusions on the grounded screen which have been found by the inventors to enhance back corona to a greater degree than sharply protrusions alluded to above.

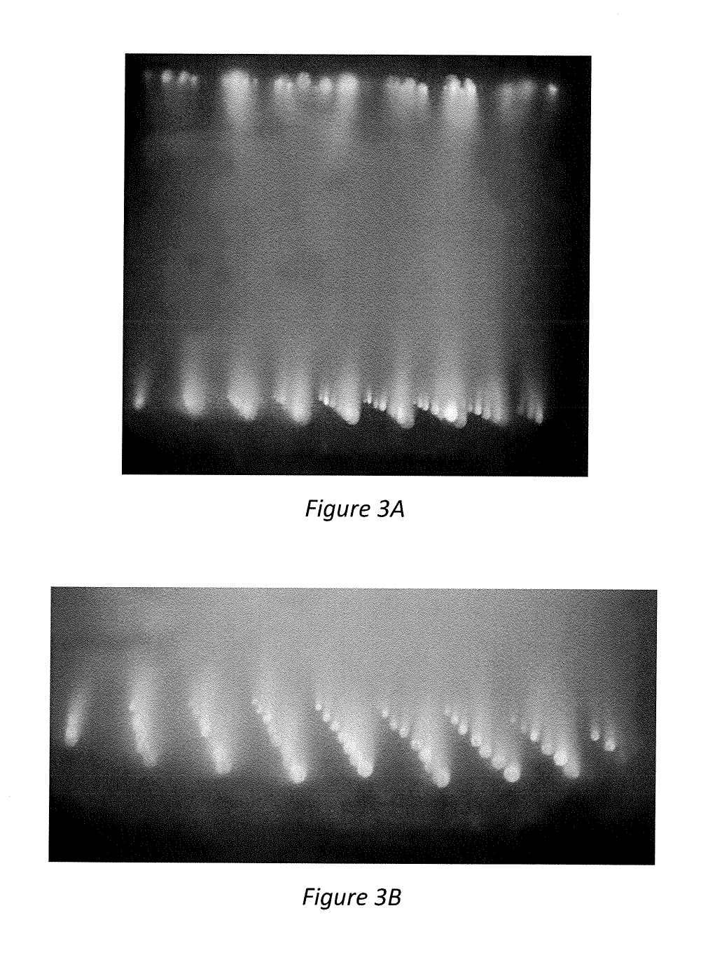

Photographs of an enhanced argon/acetylene plasma discharge produced by the invention as described above is shown in FIG. 3A in which it is seen that the intensity of the light from the back discharge appears to exceed the intensity of light from the forward discharge at the tips of the needle electrodes and that the plasma in the HV gap between the ends of the needle electrodes and the tops of the protrusions is high uniform across both the length and area of the discharge gap where the plasma is formed. FIG. 3B is a view of the grounded screen and protrusions which appears to show substantial discharge intensity across the area of the upper ends of the protrusions even though the protrusions do not include a planar upper surface but, rather, comprise only the terminal turn of a helical winding. Substantial uniformity of intensity across the entire array of protrusions is also evident. Therefore, FIGS. 3A and 3B appear to at least qualitatively indicate a significant enhancement of the plasma density and ion populations to yield enhanced populations of activated neutral radicals particularly at locations proximate to the grounded screen.

This qualitative appearance is clearly quantitatively confirmed by the measurements of discharge currents in the argon/acetylene plasma as will now be discussed in regard to FIGS. 4A-7B. Specifically, FIGS. 4A and 4B are oscillograms of the discharge currents and instantaneous voltage from which the indicated discharge power was calculated over the positive and negative half-cycles, respectively, of the energizing voltage at line frequency for a needle tip to protrusion gap of 8 cm.

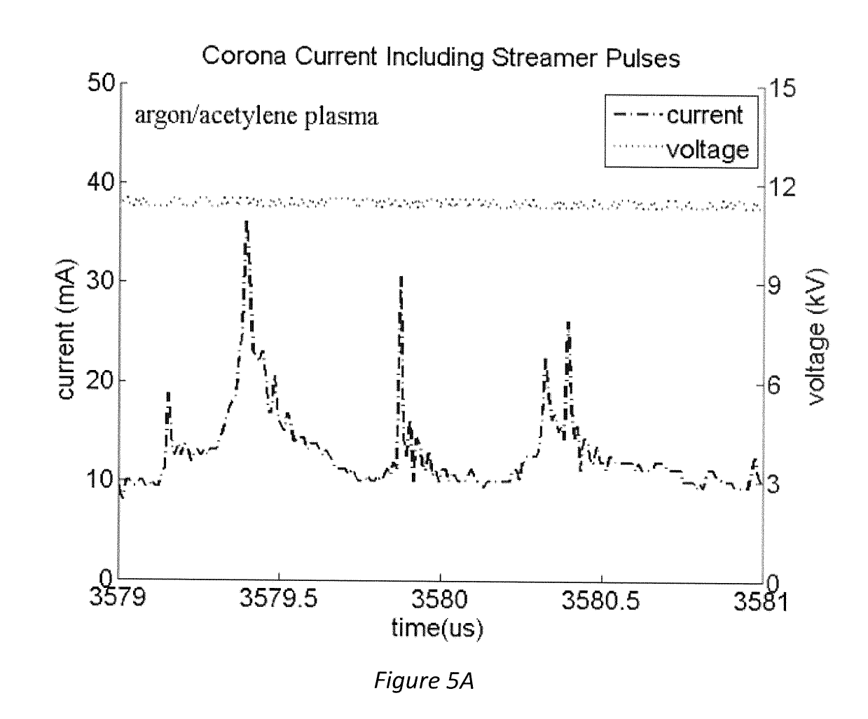

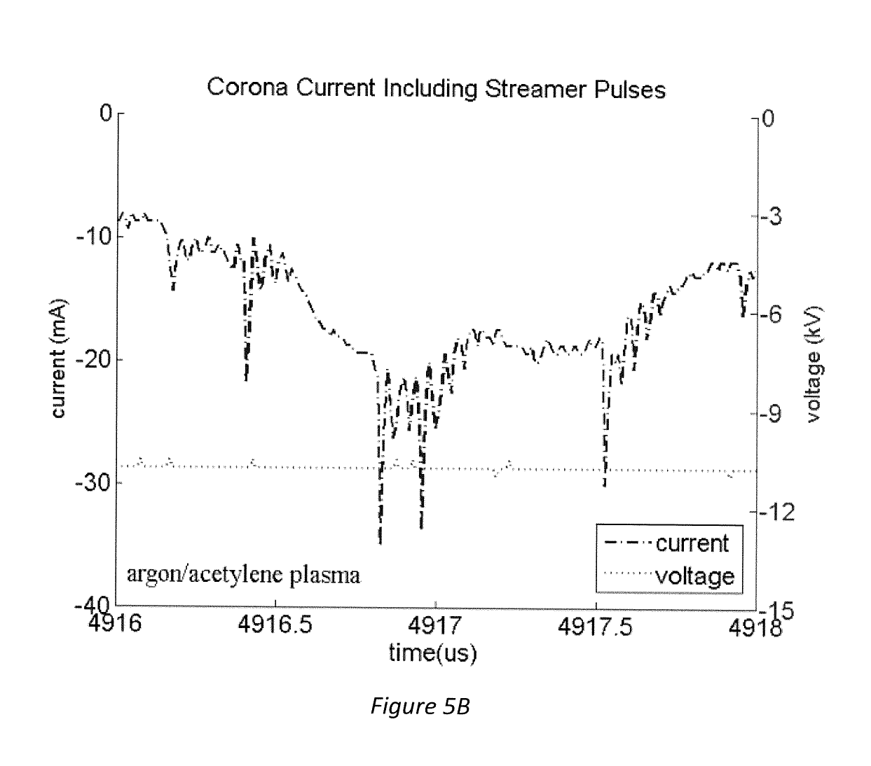

FIGS. 5A and 5B illustrate brief (2 μs duration) segments of the data presented in FIGS. 4A and 4B respectively, that clearly show the current spikes corresponding to streamers and the lower level current corresponding to glow discharge in the plasma. It should be noted that the streamer current is two to four times the corona or glow discharge current and that streamers occur with substantial frequency, including some pairs of current spikes that correspond to a pair of primary and secondary streamers. Therefore it is seen that the amount of ionization produced is large and self-sustaining. More specifically, current signals with an absolute magnitude about 0.5 mA are considered to be the (umbrella term) corona current rather than random noise signals while rapid changes in current values above 5.0 mA with rise times on the order of 10 ns are considered to be specifically associated with streamer currents (which also fall under the umbrella term corona current). It should be noted that negative half-cycle currents appear to be somewhat greater than for positive half-cycles and that the average powers for each half-cycle are larger than the discharge powers reported for plasma reactors of similar design but without the protrusions on the grounded screen. Therefore, it is believed that the number and density of the protrusions are among several possible factors contributing to the observed increase in discharge power.

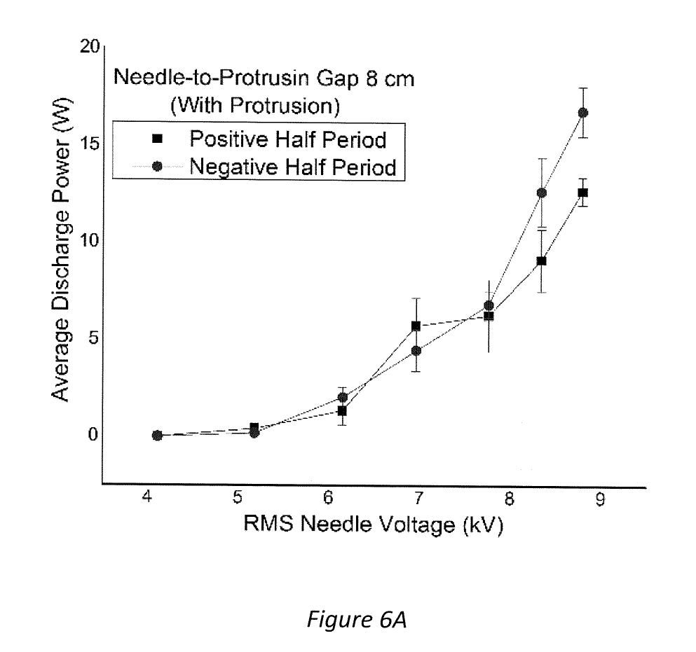

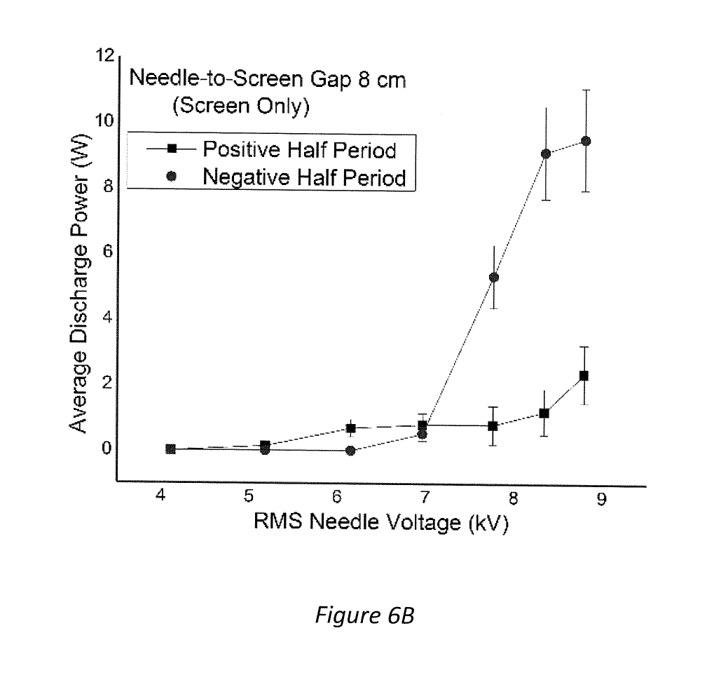

In this regard, FIGS. 6A and 6B graphically illustrate the difference in average discharge power attributable to the protrusions of positive and negative half-cycles of plasma generation. Specifically, FIG. 6A shows the average discharge power as a function of RMS needle electrode voltages for a needle to protrusion gap of 8 cm while FIG. 6B graphically illustrates average discharge power for positive and negative half cycles for an 8 cm needle to screen gap (without protrusions) consistent with all other measurement data discussed. That is the discharge gap is the same between the needle electrode tips and the protrusion tips (with protrusions, i.e. a multi-point to multi-point discharge geometry) and between the needle electrode tips and the grounded screen (without protrusions, i.e. a multi-point to plane discharge geometry). It will be noted that power during the positive and negative half-cycles are similar when protrusions are provided but diverge significantly for higher RMS needle voltages when no protrusions are provided on the grounded screen. Further, it can be clearly seen that the average discharge power for the multi-point to multi-point discharge geometry as shown in FIG. 6A is greater than for the multi-point to plane discharge geometry as shown in FIG. 6B, particularly a low to medium RMS needle electrode voltages and the positive half-cycle average power can differ between the two discharge geometries by a factor of five to seven.

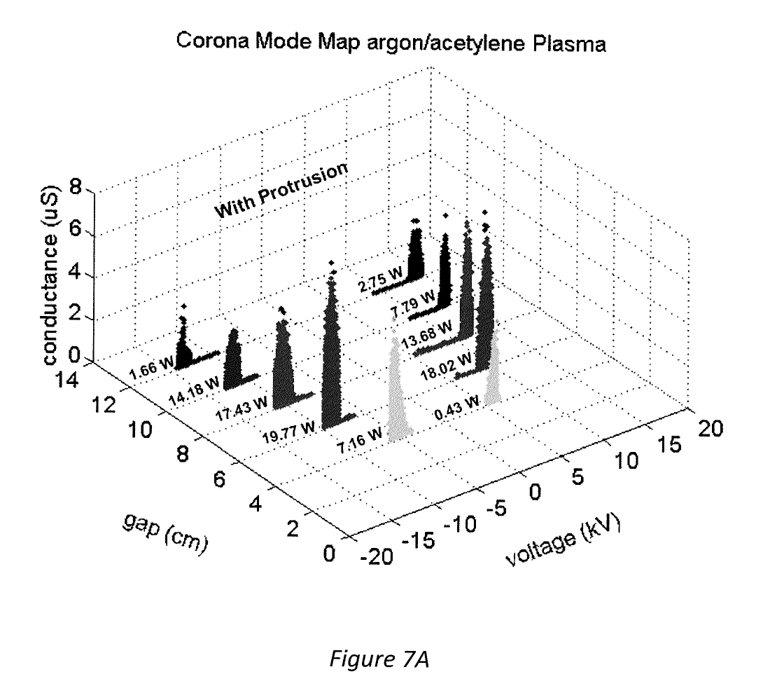

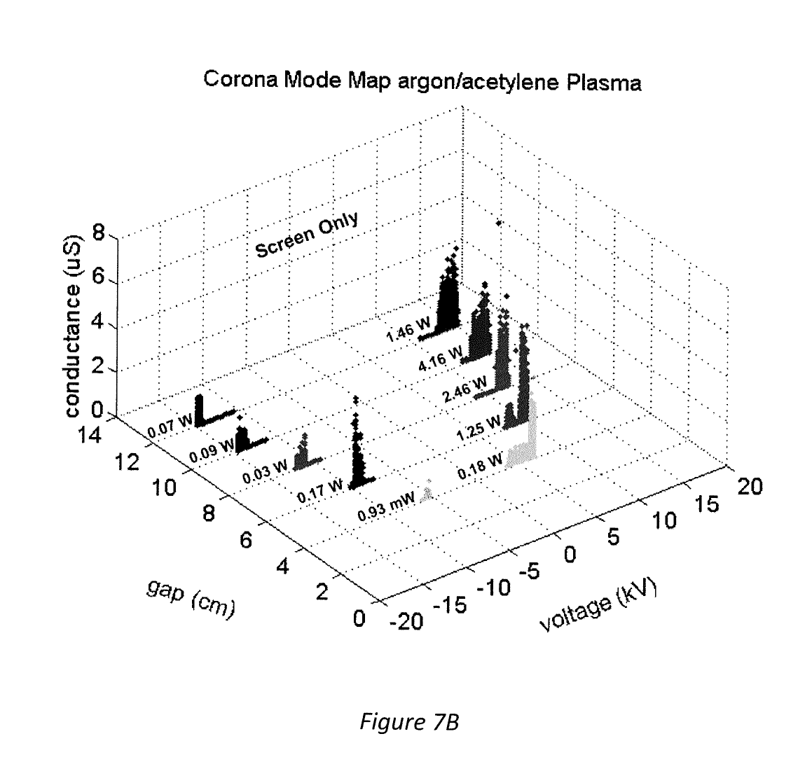

FIGS. 7A and 7B are corona mode maps for multi-point to multi-point and multi-point to plane discharge geometries, respectively and indicate conductance values for various gap spacings and voltages without any tendency toward spark discharge being caused (e.g. at gaps less than 4 cm) within the limits of available excitation voltage. It is clear from a comparison of FIGS. 7A and 7B that the protrusions play a significant role in enhancing the corona discharge modes and the increase in discharge power for the multi-point to multi-point discharge geometry. It should also be observed that these corona mode maps show no ionization in the range between −4 kV and 4 kV (peak instantaneous values, not RMS) and an enhanced back corona zone in the ranges of 7 kV to 10 kV and −7 kV to −10 kV (again, peak instantaneous values, not RMS). The gap spacing between 6 cm and 10 cm is also shown to be substantially ideal for APWIP process with enhance back corona.

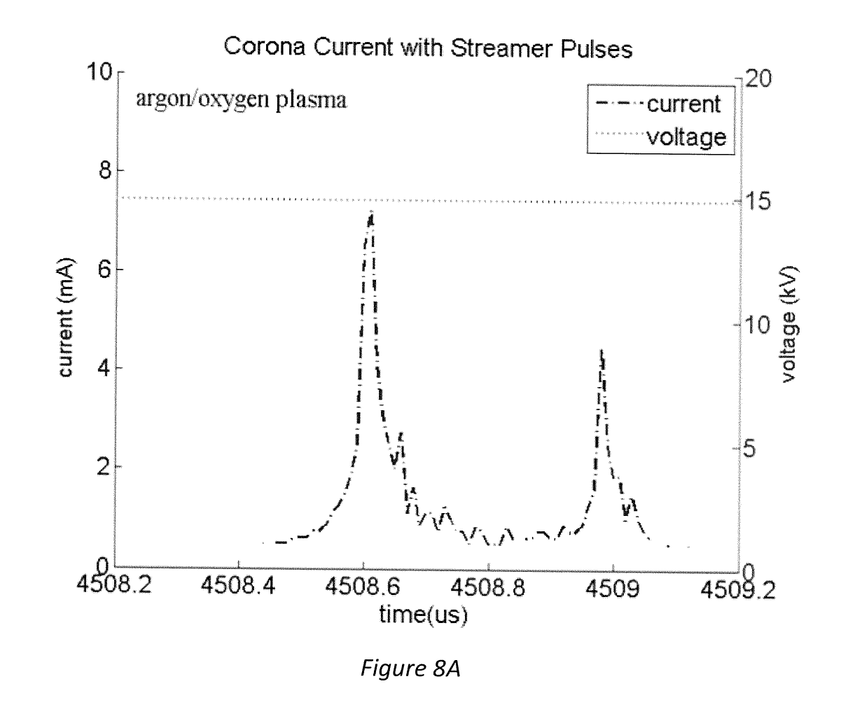

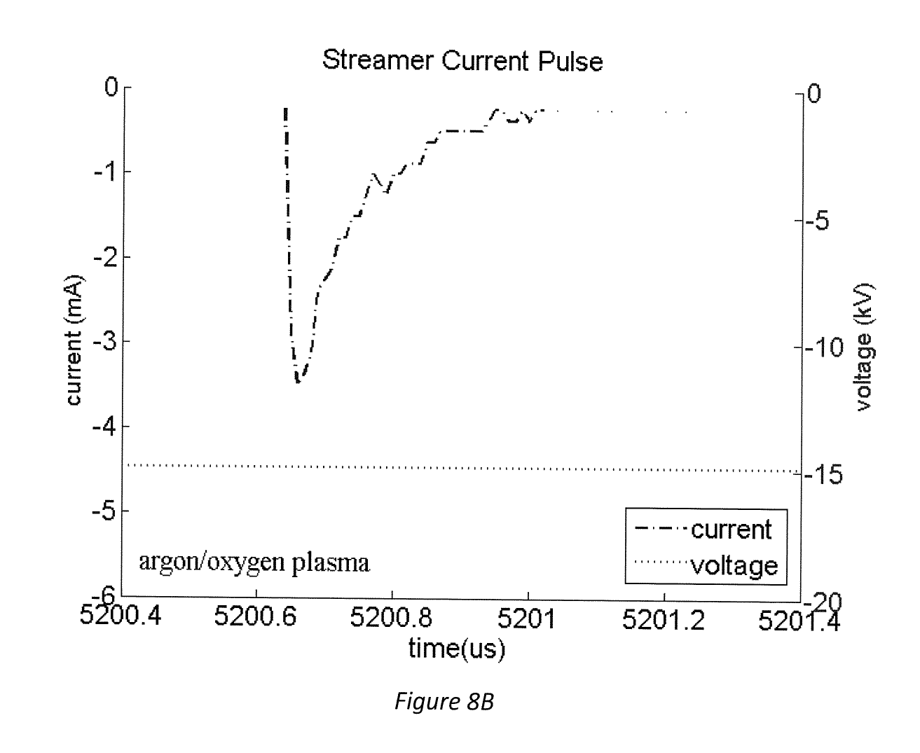

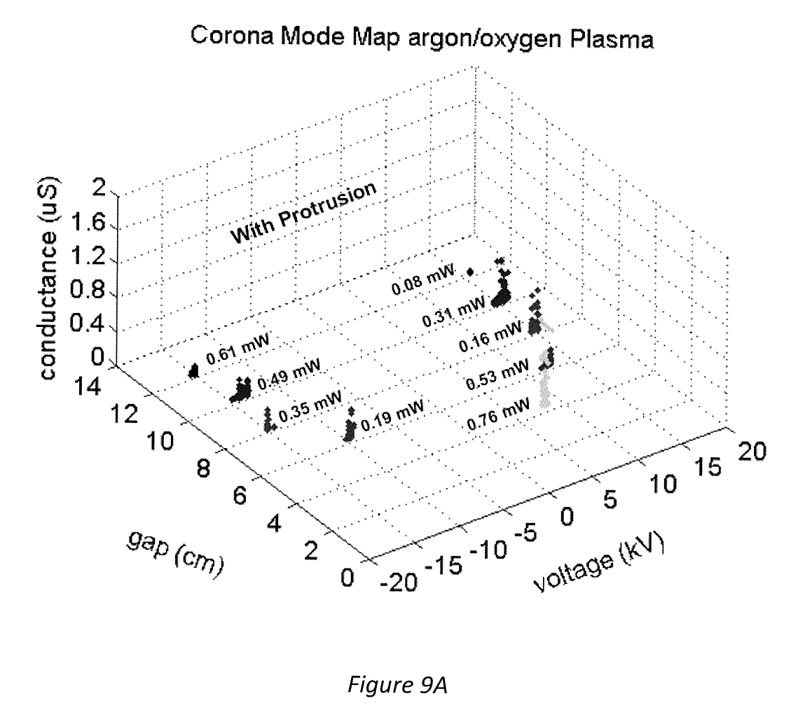

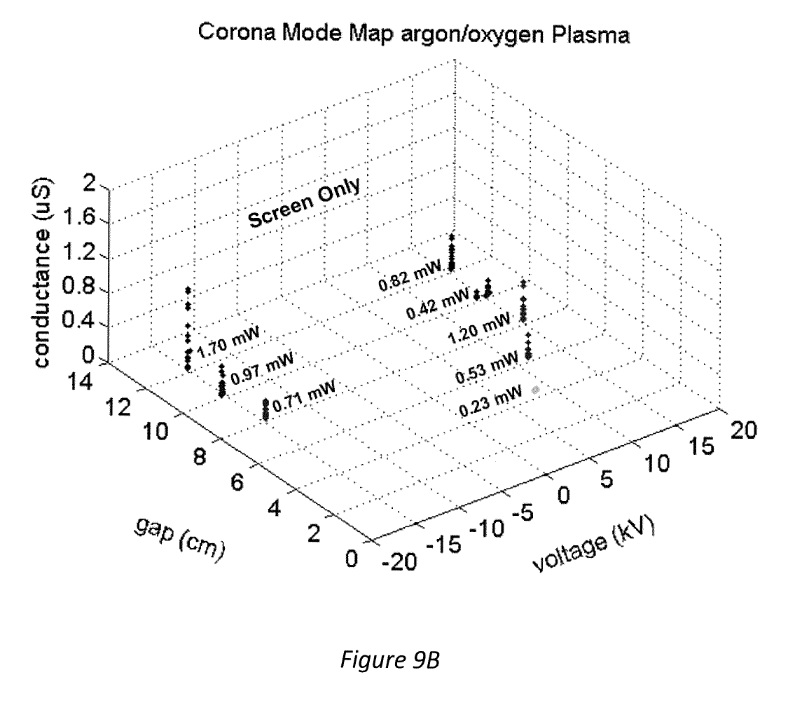

Referring now to FIGS. 8A and 8B, a comparison of discharge currents with expanded time scale similar to those of FIGS. 5A and 5B are shown for an argon/oxygen plasma with a 2.2% concentration of oxygen in the gas mixture. It can be readily seen from a comparison of FIGS. 8A and 8B with FIGS. 5A and 5B that the currents for both half-cycles of the plasma discharge are significantly lower and, more importantly, the frequency of streamer discharge peak are markedly less frequent. The glow observed at the tips of the needle electrodes was substantially less luminous and glow observed at less than all of the protrusion tips. the conductance plot in the corona mode map of FIGS. 9A and 9B shows some significant improvement of the multi-point to multi-point discharge, shown in FIG. 9A, over the multi-point to plane discharge, shown in FIG. 9B, although the difference is less than that evident in FIGS. 7A and 7B, but both Figures indicate a lack of continuous and self-sustaining streamers. The discharge powers measure at different gap lengths are very low and typically around 1 mW.

While the reasons for this difference in discharge currents between acetylene and oxygen gas mixtures is not fully understood, oxygen is electronegative and electron attachment appears to play a major role for current reduction in an Ar/O₂ plasma. It is essential to sweep away the space charge developed by the preceding streamers to a significant degree to achieve propagation of subsequent streamers. Due to the relative abundance of O₂⁻ ions present in the oxygen plasma, there might be sufficient shielding effect between positive and negative space charge to inhibit streamer propagation. Some studies have suggested that streamer decay may be due to quenching of excited argon by O₂ molecules rather than by electron attachment to O₂. On the other hand, the electron attachment to closed-shell acetylene molecules is subjected to auto-detachment while the electron impact ionization and dissociative ionization yield mostly positive ions, electrons and radicals. The positive ions drifting toward the cathode are either absorbed by the cathode or neutralized by the electrons to effectively evacuate the space charge in the gap region or plasma zone of the reactor vessel for continuous streamer propagation in the argon/acetylene plasma.

In either case, the activated neutral radicals generated by bond scission is the key to material processing outside the harsh corona environment. Due to the field enhancement of the back corona near the grounded screen by the protrusions in accordance with the invention, a high neutral radical flux can be generated near the grounded screen at least for argon/acetylene plasmas. This neutral radicle flux can transport downstream in the gas mixture flow to locations below the grounded screen and finds suitable nucleation sites on the substrate material before they are quenched.

As alluded to above, many potential practical applications of plasma processes often require gases such as nitrogen, oxygen, dry air, and carbon dioxide which are not conductive to sustainable continuous discharge at atmospheric pressure as was demonstrated above for the case of an argon/oxygen gas mixture even though noble gases such as helium, argon, and neon have a low ionization potential and yield long-lived metastable species that can sustain uniform plasma discharge. The noble gases can facilitate ionization and generation of active species in commonly used gases such as CH₄ and C₂H₂ as was demonstrated above, because of ionizing energy transfer known as “Penning transfer”. On the other hand, electronegative gases such as oxygen can substantially slow the ionization process through electron attachment. That is, in the case of argon, the excited argon species are quenched by molecular and neutral radical oxygen in an argon/oxygen plasma which significantly attenuates streamer production. However, it has also been found by the inventors that the discharge powers may be substantially increased and streamer frequency improved to self-sustaining levels by substituting helium for argon as the noble/inert gas.

Specifically, for gases that tend to attenuate streamer production noble gases that provide high energy metastable species can improve the sustainability of a plasma discharge and helium provide such high energy species that are long-lived and which can provide greater numbers of seed electrons to sustain the plasma discharge. However, such sustained plasma discharges have principally been produced with dielectric barrier discharge (DBD) plasma reactor configurations to limit a somewhat increased tendency toward a streamer-to-spark transition and not with a plasma reactor vessel in accordance with the invention to produce a multi-point to multi-point corona discharge that does not produce sparks.

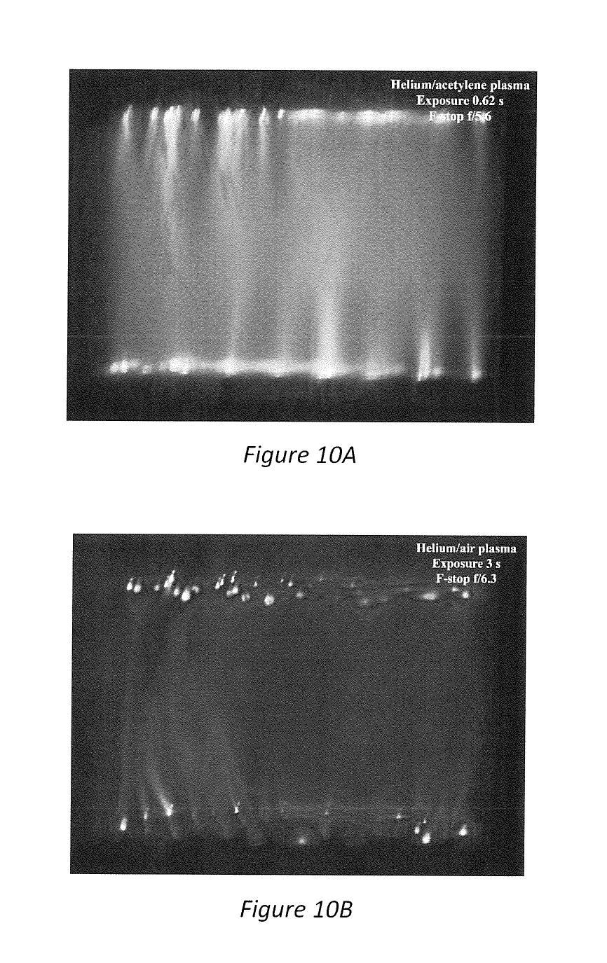

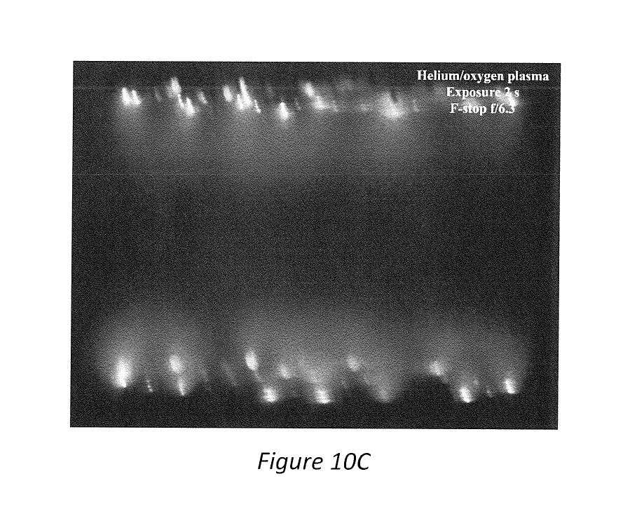

FIGS. 10A-10C provide a comparison of the appearance of helium/acetylene, helium/oxygen, and helium/dry air gas mixtures. The photographs of FIG. 10A-10C were, for purposes of comparison, made using the reactor chamber of FIG. 1 with an 8 centimeter gap spacing and an excitation voltage of 8.4-9.2 kV RMS and further optimization for particular gas mixtures is therefore possible. While the helium/oxygen and helium/dry air plasmas are of much lower visual intensity by a factor of about four to ten across the gap, relatively strong luminosity comparable to that of the forward discharge at the HV needle electrodes is observed at most of the protrusions; indicating a strong enhancement of the back corona discharge close to the grounded screen. While the visual intensity of the helium/dry air plasma (which contains significantly more nitrogen than oxygen) is lower (by about a factor of two) than that of the helium/oxygen plasma, the enhancement of the back corona discharge is still very evident and that similar results may be obtainable for a helium/nitrogen plasma.

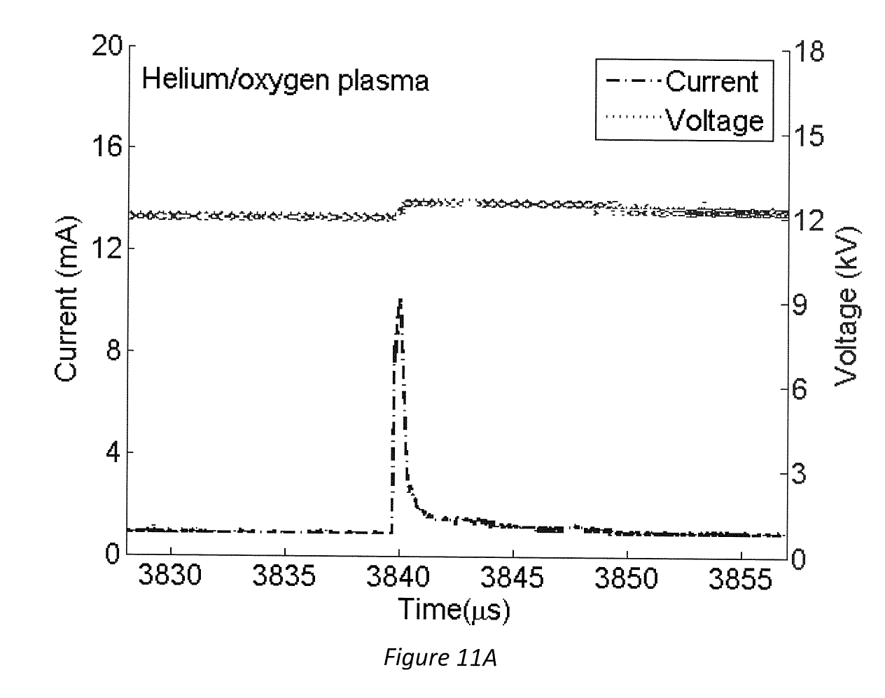

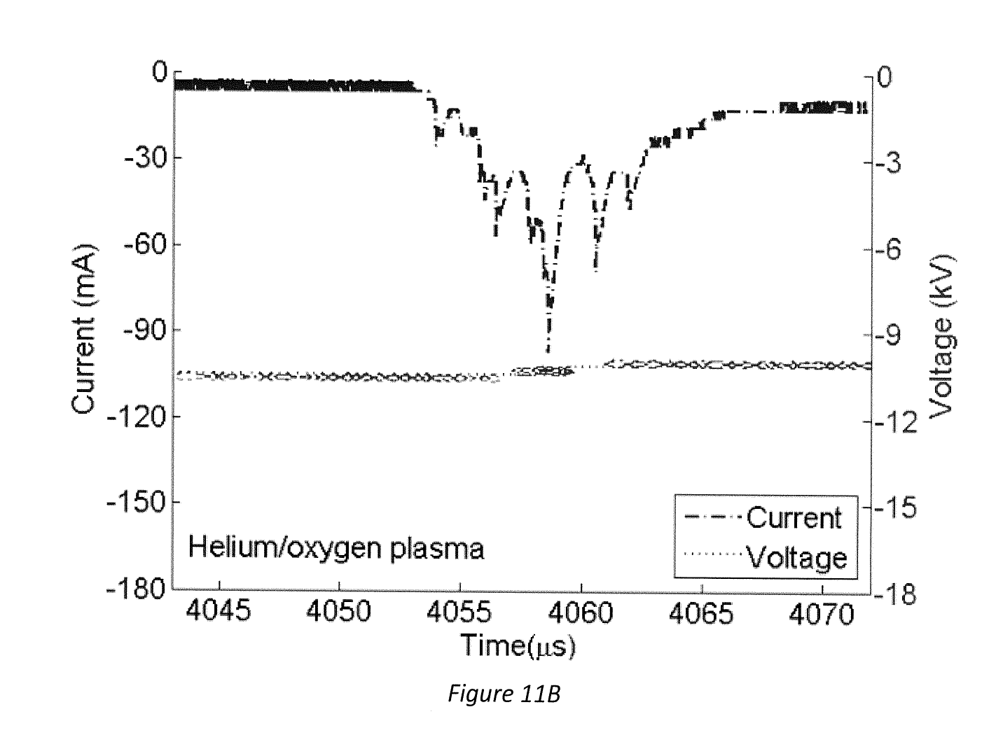

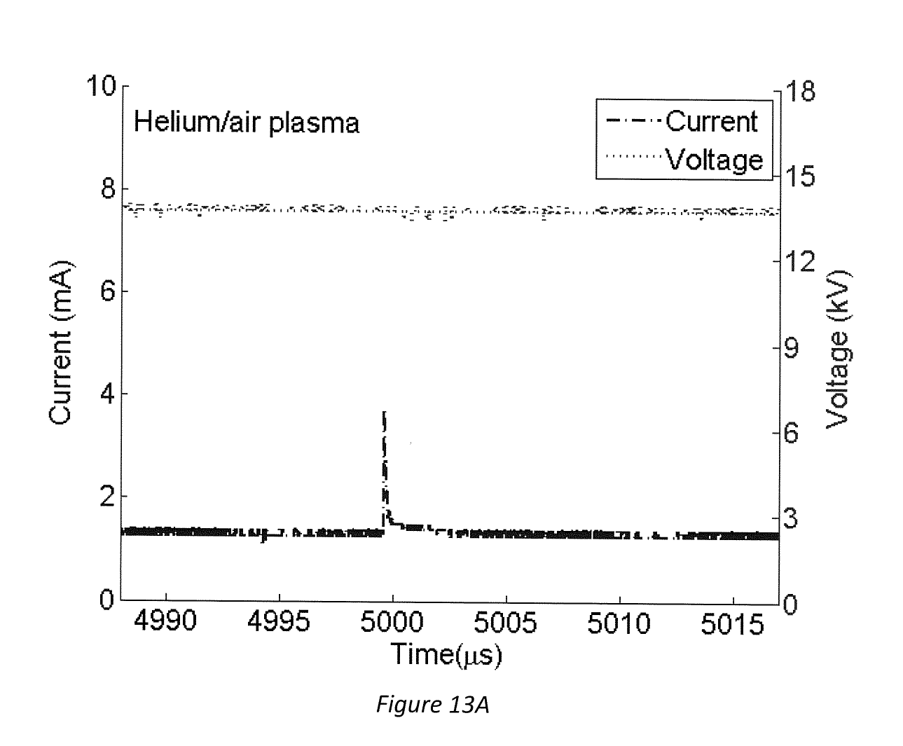

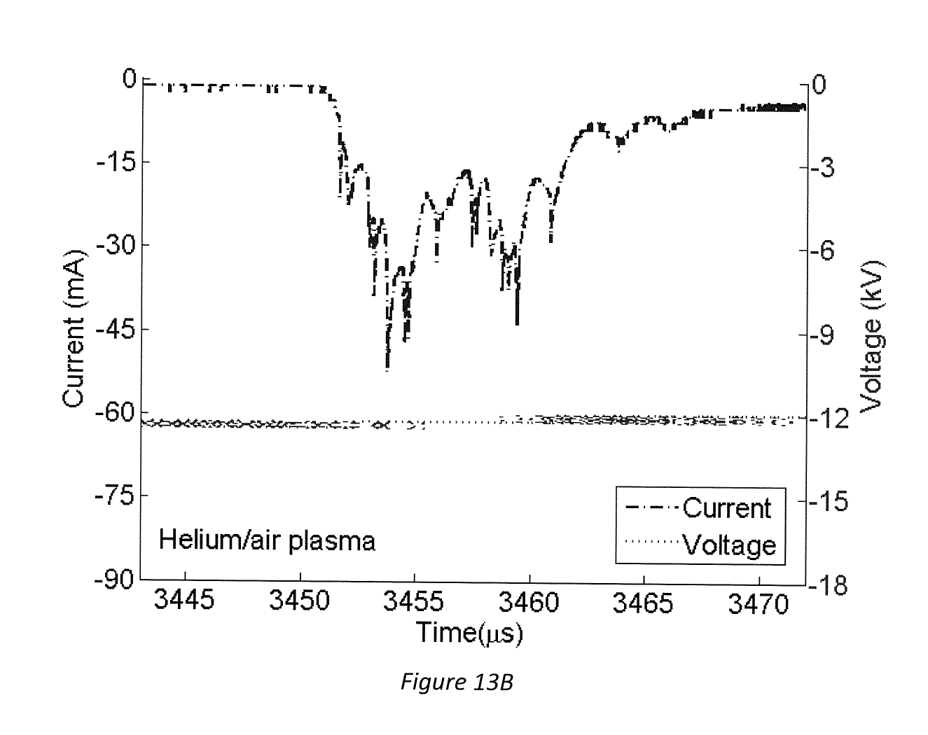

Quantitatively, a time-base expanded oscillograph of the positive and negative half cycle streamer discharges in a helium/oxygen plasma are shown in FIGS. 11A and 11B, respectively. Similar oscillographs for a helium/dry air plasma are shown in FIGS. 13A and 13B respectively. It is observed that the number and frequency of streamer discharges is substantially greater in the negative half-cycle than in the positive half-cycle and that the difference is somewhat greater for the helium/dry air plasma. The peak current levels of the streamers in the helium/oxygen plasma are about three-fourths of the peak current levels in a helium/acetylene plasma. The peak current levels of the streamers in the helium/dry air plasma are about one half of the peak current levels in a helium/acetylene plasma. Both plasmas provide current peaks far greater than those observed for an argon/oxygen plasma (e.g. FIGS. 8A and 8B).

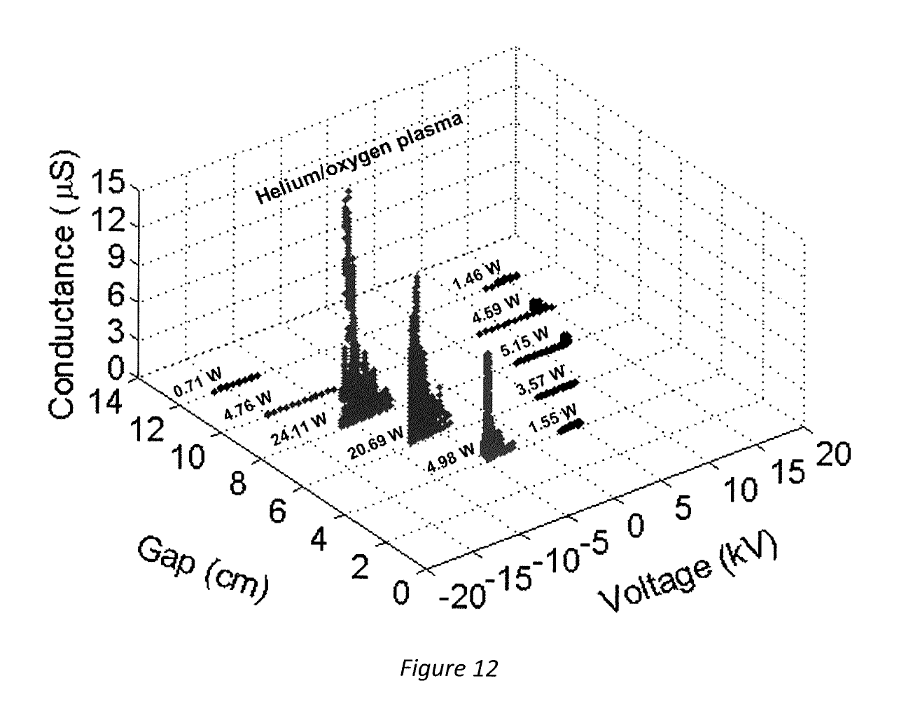

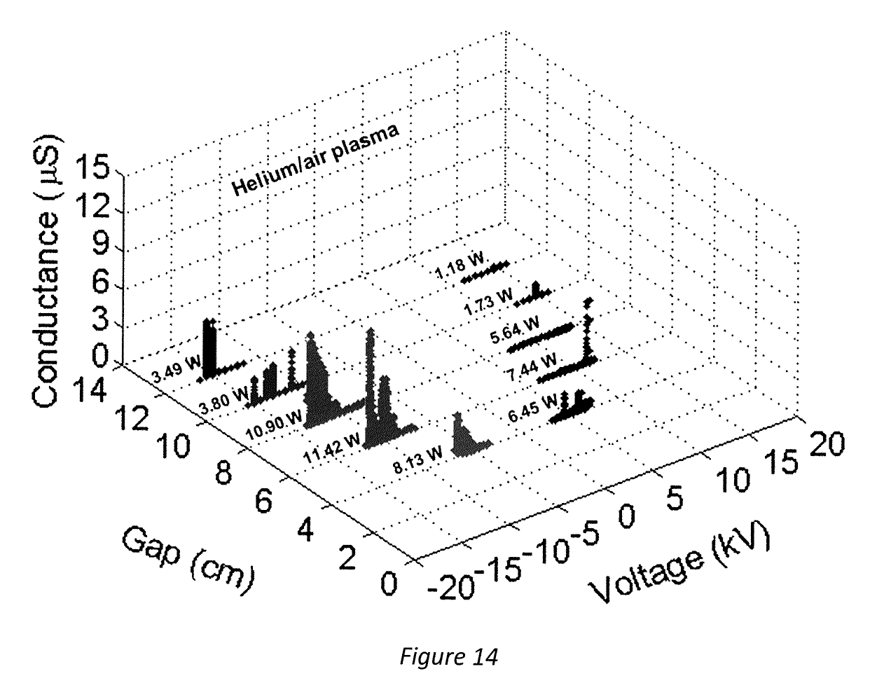

Discharge mode maps for helium/oxygen and helium/dry air plasmas are shown in FIGS. 12 and 14, respectively. Even though relatively high conductance values are essentially confined to one half-cycle of the excitation voltage, the conductances are significant and vary fairly strongly with the reaction vessel electrode gap; indicating not only practical and usable levels of neutral radicals for material treatment processes not previously possible but that some optimization may yield larger quantities of neutral radicals for improved material treatment and the possibility of extrapolation to nitrogen. In any case, the reactor vessel in accordance with the invention is scalable to any size with or without optimization to produce sufficient numbers of neutral radicals for plasma treatment processes requiring near atmospheric pressure that, as a practical matter, were not possible prior to the invention.

In view of the foregoing, it is seen that the use of protrusions held at ground potential on a grounded screen and a gas mixture that is predominantly an inert/noble gas greatly enhances back corona discharge and production of neutral radicals below the grounded screen for plasma treatment of materials or other objects outside the harsh environment of a plasma at near atmospheric pressures. Substitution of helium for argon where argon does not provide a sustainable streamers discharge production yields practical and usable quantities of neutral radicals of gases, such as oxygen and dry air without spark production.

While the invention has been described in terms of a single preferred embodiment, those skilled in the art will recognize that the invention can be practiced with modification within the spirit and scope of the appended claims.

Having thus described my invention, what I claim as new and desire to secure by Letters Patent is as follows:

1. A plasma reactor vessel capable of producing a plasma at near-atmospheric pressures, said plasma reactor vessel comprising:
an enclosure having an inlet and outlet for a gas mixture and establishing a gas flow, said gas mixture being predominantly an inert gas to inhibit quenching of inert radicals in said enclosure,
an array of needle shaped high voltage electrodes connected to a high voltage source,
a screen at substantially ground potential,
an array of protrusions having blunt profiles and extending toward said array of needle shaped high voltage electrodes, said array of protrusions being at substantially said potential of said screen,
a workpiece support proximate to a side of said screen opposite to said protrusions,
whereby back corona discharge and ion production are enhanced near said screen and ions of a gas in said gas mixture are neutralized at said screen to become neutral radicals which are transported to a location of said workpiece support by said gas flow before being quenched.

2. The plasma reactor vessel as recited in claim 1, wherein said gas mixture in includes and inert gas.

3. The plasma reactor vessel as recited in claim 2 wherein said inert gas is one of argon and helium,

4. The plasma reactor vessel as recited in claim 1, wherein said gas mixture contains acetylene.

5. The plasma reactor vessel as recited in claim 1, where said gas mixture contains oxygen.

6. The plasma reactor vessel as recited in claim 5 wherein said gas mixture contains dry air.

7. The plasma reactor vessel as recited in claim 1, wherein said array of protrusion extends over an area of said grounded screen.

8. The plasma reactor vessel as recited in claim 1, wherein said protrusions are separated from each other by one centimeter.

9. The plasma reactor vessel as recited in claim 1, wherein said protrusions are one centimeter in length and have a radius of curvature of 150 micrometers.

10. The plasma reactor vessel as recited in claim 1, wherein said grounded screen includes a ring at its periphery and springs attached to said ring to bear against an interior surface of said enclosure.

11. The plasma reactor vessel as recited in claim 1, wherein said protrusions are supported on a conductive lattice.

12. The plasma reactor vessel as recited in claim 1, wherein tips of said needle electrodes are coplanar.

13. The plasma reactor vessel as recited in claim 1, wherein tips of said protrusions are coplanar.

14. A method of treatment of a material with a plasma at near atmospheric pressure, said method comprising steps of
diluting a precursor or reactant gas with a predominant amount of an inert gas to provide a gas mixture at near atmospheric pressure,
producing a flow of said gas mixture through a plasma reactor vessel, and
applying a high voltage to an array of elongated needle electrodes to cause a multi-point to multi-point plasma discharge between said needle electrodes and protrusion supported and electrically connected to a grounded screen,
whereby back corona discharge is enhanced at a location proximate to said grounded screen and neutral radicals pass through said grounded screen to a workpiece.

15. The method as recited in claim 14, wherein said inert gas is argon or helium.

16. The method of claim 14 wherein said reactant or precursor gas contains acetylene, oxygen or dry air.

17. The method as recited in claim 14, including a further step of
adjusting a gap between said needle electrodes and said protrusions.

18. The method as recited in claim 14, including the further step of adjusting a level of said high voltage.
